(19) United States
(12) Patent Application Publication
(10) Pub. No.: US 2008/0083732 A1
(43) Pub. Date: Apr. 10, 2008

(54) Wafer holder and exposure apparatus equipped with wafer holder

(75) Inventors: Kenji Shinma, Itami-shi (JP); Hirohiko Nakata, Itami-shi (JP); Masuhiro Natsuhara, Itami-shi (JP)

Correspondence Address: GLOBAL IP COUNSELORS, LLP, 1233 20TH STREET, NW, SUITE 700, WASHINGTON, DC, 20036-2680, US

(73) Assignee: Sumitomo Electric Industries, Ltd., Osaka-shi (JP)

(21) Appl. No.: 11/544,636

(22) Filed: Oct. 10, 2006

(51) Int. Cl. B05C 13/00; C23C 16/00

(52) U.S. Cl. 219/444.1; 118/500; 118/725; 219/385

(57) ABSTRACT

The present invention is a wafer holder including a heating plate 2 equipped with heating means such as a film-form/foil-form heat generating body 9 or the like, a cooling plate 3 equipped with cooling means such as a coolant passage 7 or the like, and temperature measurement means 4, wherein the heating plate 2 and cooling plate 3 are layered in a direction perpendicular to the wafer placement surface. The heating plate 2 is preferably disposed closer to the wafer placement surface than the cooling plate 3, and a heat conducting member 8 is disposed between the heating plate 2 and cooling plate 3.

### BACKGROUND OF THE INVENTION

1. Field of the Invention

The present invention relates to a wafer holder that performs heating and cooling of semiconductor wafers in a semiconductor device manufacturing process, and more particularly relates to a wafer holder that is suitable for use in an exposure apparatus.

2. Description of the Background Art

Generally, circuit formation in a semiconductor device manufacturing process is accomplished with a process in which a semiconductor wafer is coated with a resist by a spin coater, and is then dried and baked, after which the wafer is irradiated with ultraviolet light by an exposure apparatus, so that the circuit is baked on.

In recent years, as circuit patterns formed on semiconductor devices have become progressively finer, circuit widths have dropped below 0.1 μm. In cases where such fine circuit patterns are formed on semiconductor wafers, even a slight deviation in the exposure position where the resist is exposed results in defects in the circuit that is ultimately formed.

One of the main causes of such deviation in the exposure position is thermal expansion of the semiconductor wafer. Accordingly, in the exposure process, strict control of the semiconductor wafer temperature to a specified temperature is important. Recently, furthermore, since large semiconductor wafers having a diameter of 200 mm or 300 mm have been used, it has become extremely difficult to obtain the same temperature over the entire surface of the wafer.

Accordingly, the provision of a Peltier element used to adjust the temperature and a heating pipe used to diffuse heat over the entire surface of the wafer holder has been proposed in Japanese Laid-Open Patent Publication No. 05-21308 as a method of solving this problem. Furthermore, the installation of a plurality of Peltier elements and temperature sensors on the wafer holder has been proposed in Japanese Laid-Open Patent Publication No. 11-168056. Furthermore, a method in which the temperature of the wafer is adjusted by using a heating lamp or a heater in combination with a Peltier element has been proposed in Japanese Laid-Open Patent Publication No. 2003-31470.

### SUMMARY OF THE INVENTION

In the methods of the respective patent references described above, the temperature of the wafer holder can be precisely controlled to a specified temperature. However, circuits with even finer circuit patterns have been required, and in order to improve the throughput, it is necessary to set the wafer temperature even more precisely than in the past, and to make this temperature uniform in a short period of time. It cannot be said that the temperature control characteristics obtained in the abovementioned methods are completely adequate.

For example, in the method combining a Peltier element and heating pipe described in Japanese Laid-Open Patent Publication No. 05-021308 and the method installing a plurality of Peltier elements and temperature sensors described in Japanese Laid-Open Patent Publication No. 11-168056, because of restrictions that prevent the manufacture of small Peltier elements and heating pipes, there are limits to the extent that the temperature can be made uniform. Furthermore, in the method combining a Peltier element and a heating lamp or a heater described in Japanese Laid-Open Patent Publication No. 2003-031470, there are limits to the extent that the temperature can be made uniform in cases where a heating lamp is used. In cases where a heater is used, although this is effective in controlling the temperature at the measurement location in a short period of time, the uniformity of the temperature over the entire surface of the wafer conversely tends to show a deterioration in most cases when these parts are simply used in combination.

The present invention was devised in the light of such problems in the conventional technology. It is an object of the present invention to provide a wafer holder which can make the temperature of a semiconductor wafer placed on the wafer holder uniform with high precision in a short period of time over the entire surface of the wafer, and to provide an exposure apparatus using this wafer holder in which there is no deviation in the exposure position.

In order to achieve the abovementioned object, the wafer holder provided by the present invention is a wafer holder in which a semiconductor wafer is placed on a wafer placement surface and heated, this wafer holder comprising a heating plate equipped with heating means, a cooling plate equipped with cooling means, temperature measurement means for measuring the temperature of the wafer holder, wherein the heating plate and the cooling plate are stacked in a direction perpendicular to the wafer placement surface.

In the abovementioned wafer holder of the present invention, it is desirable that the heating plate be disposed closer to the wafer placement surface than the cooling plate. Furthermore, it is desirable that a heat conducting member be disposed between the heating plate and the cooling plate.

Furthermore, in the abovementioned wafer holder of the present invention, it is desirable that the cooling means perform cooling at a constant output, and that the heating means be controlled on the basis of the temperature measured by the abovementioned temperature measurement means. Moreover, a Peltier element may be installed between the cooling plate and the heat conducting member.

In the abovementioned wafer holder of the present invention, it is desirable that the temperature measurement means be disposed in the heat conducting member. Furthermore, it is desirable that the distance between the temperature measurement means and the heating plate be equal to or less than ½ of the thickness of the heat conducting member. In particular, it is especially desirable that the temperature measurement means contact the heating plate.

Furthermore, in the abovementioned wafer holder of the present invention, it is desirable that the planarity of the heat conducting member be 30 μm or less, and a planarity of 10 μm or less is even more desirable. Furthermore, it is desirable that the surface roughness Ra of the contact surface of the heat conducting member with the cooling plate and the contact surface of the heat conducting member with the heating plate be 3 μm or less, and the surface roughness of 1 μm or less is even more desirable.

In the abovementioned wafer holder of the present invention, it is desirable that the abovementioned heating plate be a heating plate in which a metallized thin film, metal foil, or metal coil is installed as a heating means inside or on the surface of a ceramic substrate. Furthermore, the thermal conductivity of the ceramic substrate constituting the heating plate is preferably 30 W/mK or greater, more preferably 50 W/mK or greater, and even more preferably 150 W/mK or greater. It is desirable that this ceramic substrate be made of aluminum nitride.

In the abovementioned wafer holder of the present invention, the product of the specific heat and density of the heat conducting member is preferably 2.0 J/cm³K or greater, more preferably 2.3 J/cm³K or greater, and even more preferably 3.0 J/cm³K or greater. Furthermore, it is desirable that this heat conducting member be made of copper or a copper alloy.

In the abovementioned wafer holder of the present invention, it is desirable that the target temperature of the wafer holder be set at a temperature between 10° C. and 40° C., and that the heating plate, the heat conducting member, and the cooling plate be pressed to form contacts.

Furthermore, the present invention provides an exposure apparatus which is equipped with the abovementioned wafer holder.

In the present invention, the temperature of the semiconductor wafer placed on the wafer holder can be made uniform over the entire surface of the wafer with extremely high precision in a short time. Accordingly, by using this wafer holder, it is possible to provide an exposure apparatus which provides no deviation in the exposure position, and which can handle the formation of extremely fine patterns.

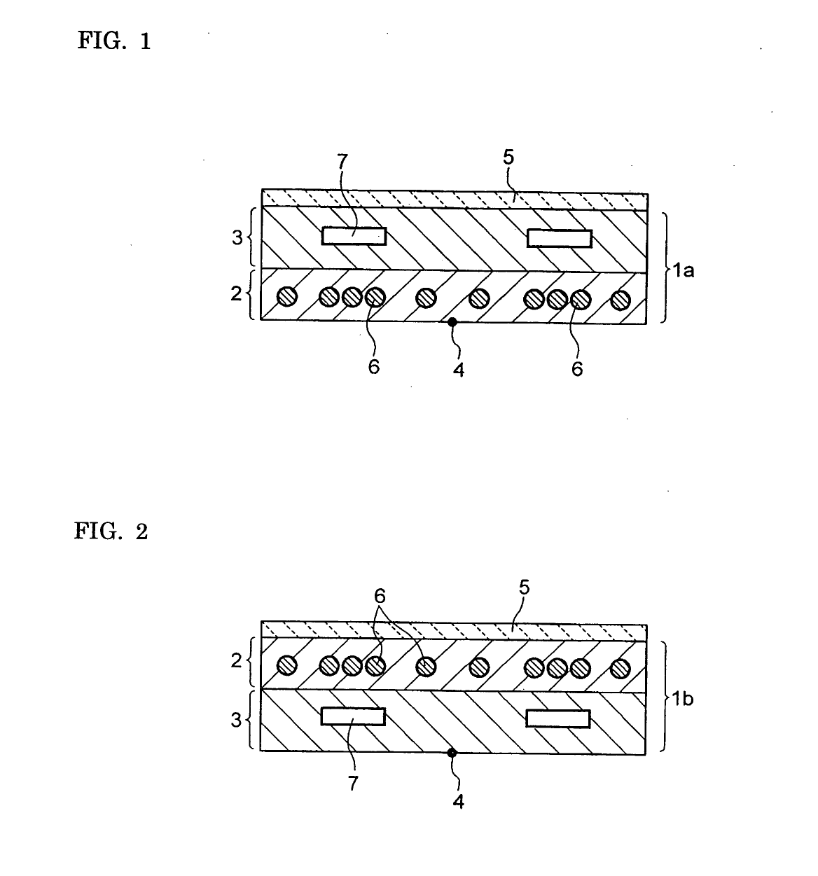

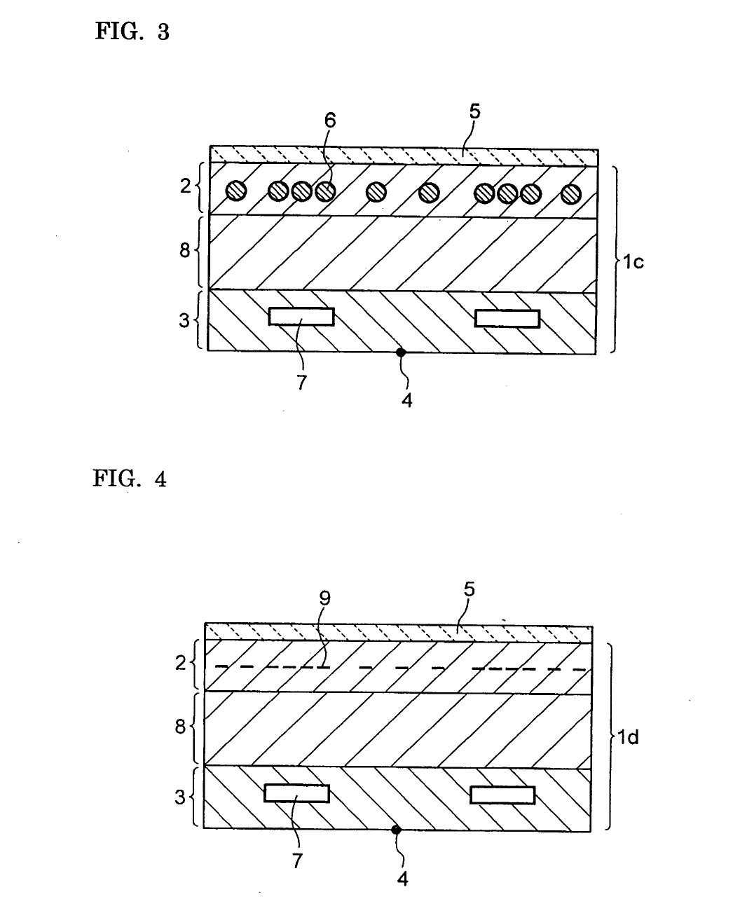

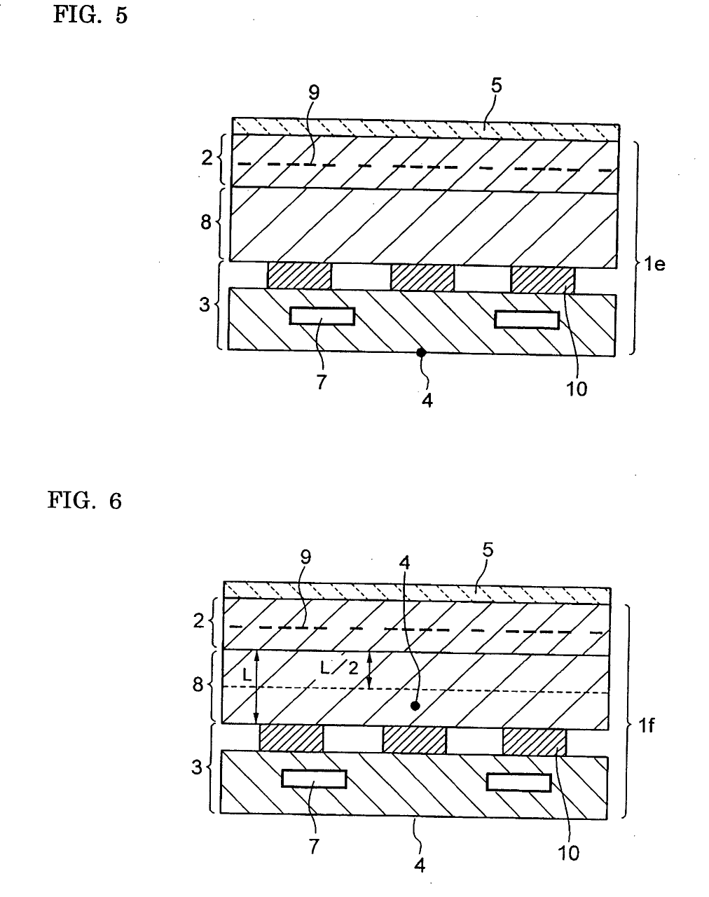

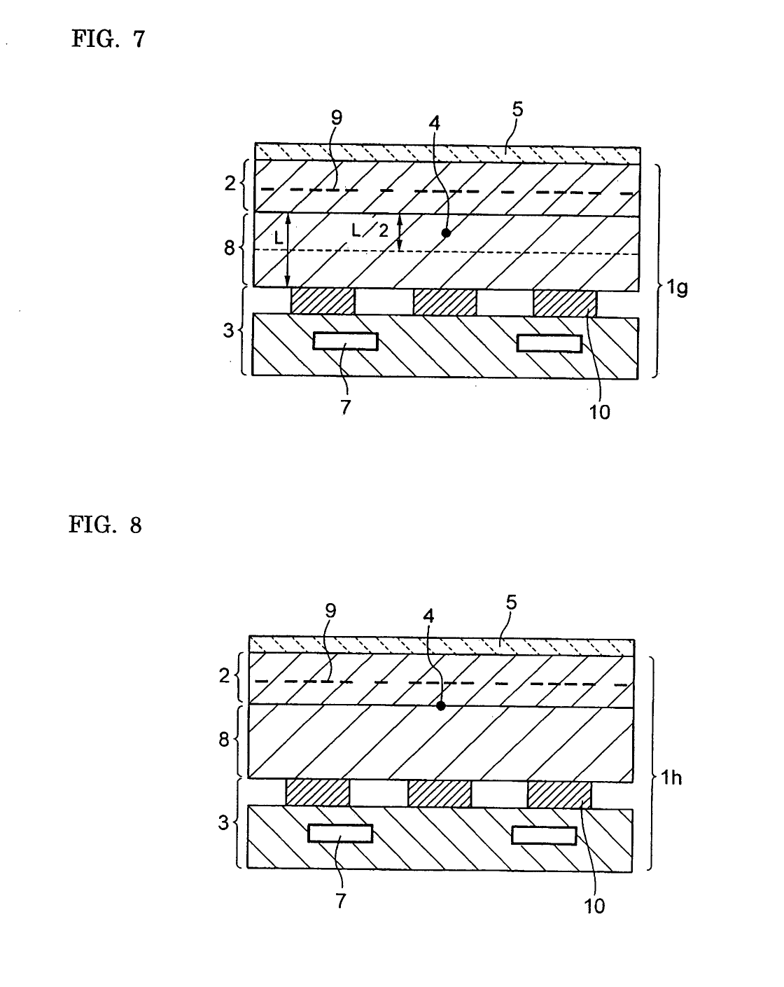

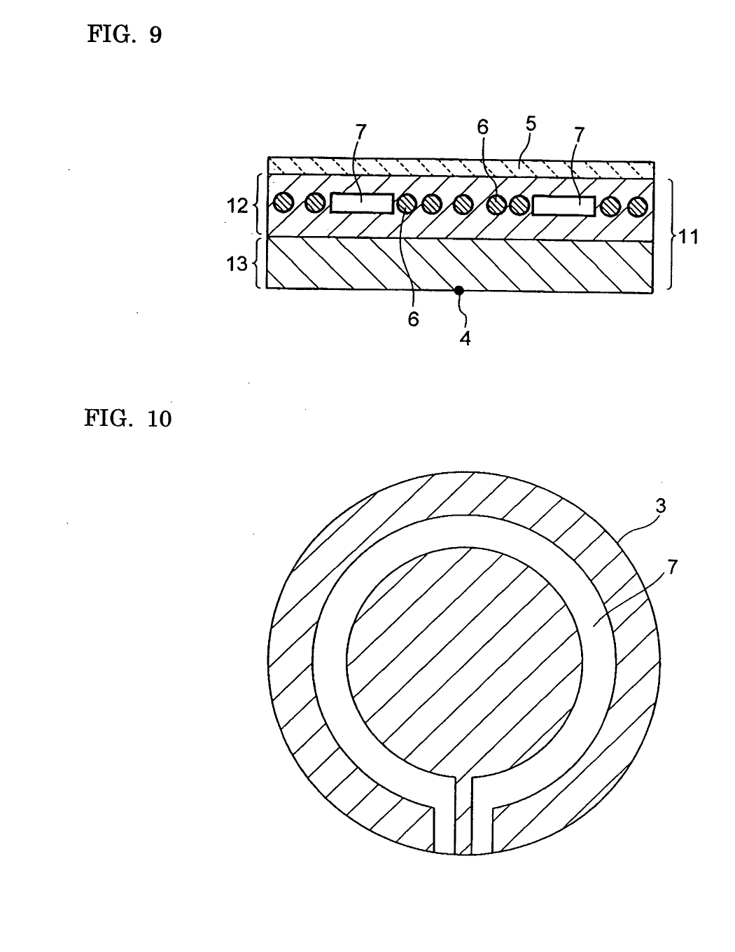

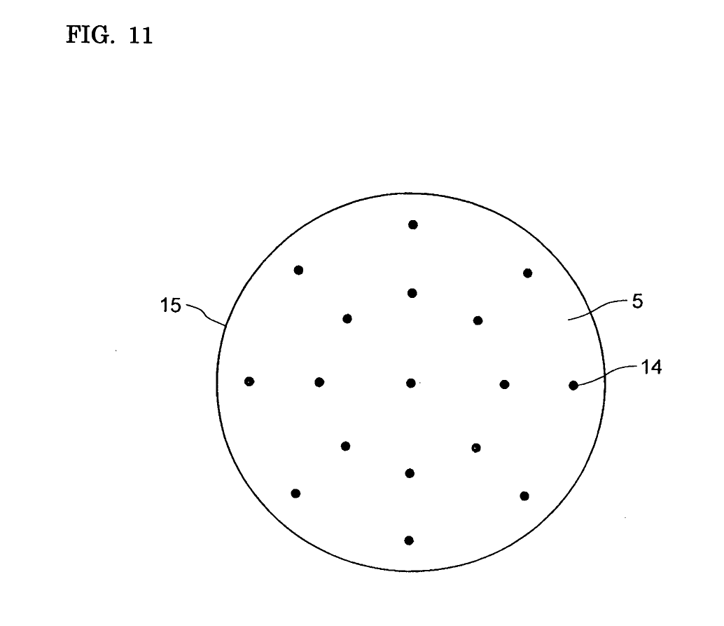

### BRIEF DESCRIPTION OF THE DRAWINGS

[FIG. 1] Schematic cross sectional view showing the basic layered structure in the wafer holder of the present invention.

[FIG. 2] Schematic cross sectional view showing another basic layered structure in the wafer holder of the present invention.

[FIG. 3] Schematic cross sectional view showing the layered structure including the heat conducting member in the wafer holder of the present invention.

[FIG. 4] Schematic cross sectional view showing another layered structure including the heat conducting member in the wafer holder of the present invention.

[FIG. 5] Schematic cross sectional view showing the layered structure including the heat conducting member and the Peltier elements in the wafer holder of the present invention.

[FIG. 6] Schematic cross sectional view showing another layered structure including the heat conducting member and the Peltier elements in the wafer holder of the present invention.

[FIG. 7] Schematic cross sectional view showing still another layered structure including the heat conducting member and the Peltier elements in the wafer holder of the present invention.

[FIG. 8] Schematic cross sectional view showing a layered structure combining the heat conducting member and the Peltier elements in which the temperature measurement means contacts the heating plate in the wafer holder of the present invention.

[FIG. 9] Schematic cross sectional view showing a conventional wafer holder.

[FIG. 10] Schematic cross sectional view showing the shape of the coolant passage of the cooling plate in the present invention.

[FIG. 11] Schematic cross sectional view showing the wafer temperature gauge in which the resistance temperature detectors are embedded in the semiconductor wafer.

### DETAILED DESCRIPTION OF THE INVENTION

In conventional wafer holders, a heating means and a cooling means are disposed substantially on the same plane. For example, inside a substrate made of an aluminum alloy or the like, the heating means such as a molybdenum coil and the cooling means such as a coolant passage or the like through which a coolant flows are disposed substantially on substantially the same plane parallel to a wafer placement surface. Furthermore, the heating means is designed so that it is disposed in a concentrated manner in the vicinity of the cooling means such as a coolant passage or the like. Ordinarily, furthermore, the output of the heating means is fixed, and the temperature of the wafer holder is controlled by adjusting the temperature of the coolant in the coolant passage. In the case of this method, however, it is difficult to obtain a uniform temperature over the entire wafer placement surface of the wafer holder.

On the other hand, in the wafer holder of the present invention, a heating plate comprising a heating means and a cooling plate comprising a cooling means are stacked in a direction forming a right angle to the wafer placement surface, i.e., are stacked so that the plane on which the heating means is disposed and the plane on which the cooling means is disposed are not the same plane, and so that these planes are parallel to the wafer placement surface. As a result of the use of a structure in which the heating plate and the cooling plate are thus stacked together, the position in which the heating means is concentrated and the position in which the cooling means is disposed substantially coincide when viewed from the wafer placement surface. Accordingly, the respective temperature variations can be mutually cancelled, so that the temperature of the wafer holder and the temperature of the semiconductor wafer carried on this wafer holder can be made precisely uniform.

Next, several examples of the wafer holder of the present invention will be described in detail with reference to the attached figures. Furthermore, parts that are the same in the respective figures are labeled with the same reference numerals. First, in a wafer holder 1a shown in FIG. 1, one surface of a cooling plate 3 forms a wafer placement surface that carries the semiconductor wafer 5, and a heating plate 2 is stacked under the cooling plate 3 (stacked on the opposite side from the wafer placement surface). In the heating plate 2, a coil-form heat generating body 6 is disposed as a heating means inside or on the surface of a ceramic substrate, and a coolant passage 7 is disposed as a cooling means inside the cooling plate 3. Furthermore, in this wafer holder 1a, a temperature measurement means 4 is disposed on the undersurface of the heating plate 2.

In the wafer holder of the present invention in which the heating plate and the cooling plate are stacked together, the positions in which the heating means and the cooling means are disposed, i.e., the position in which the coil-form heat-generating body 6 is concentrated and the position in which the coolant passage 7 is disposed in FIG. 1 substantially coincide when viewed from the side of the wafer placement surface. As a result, the position that would have an excessively high temperature in the case of the heating means alone is cooled in a concentrated manner so that the heating effect and the cooling effect cancel each other or are averaged out, thus making it possible to achieve a uniform temperature in the wafer placement surface of the wafer holder.

As another example of the wafer holder of the present invention, it is also possible to stack the heating plate 2 and the cooling plate 3 in the opposite order above and below as shown in FIG. 2. Generally, while only relatively large coolant passage 7 can be disposed and designed in the cooling plate 3, the coil-form heat-generating body 6 or other heating means can be disposed and designed in a finer configuration than the coolant passage 7. Accordingly, as is shown in FIG. 2, a wafer holder 1b in which the heating plate 2 comprising a heating means is disposed on the side of the wafer placement surface can improve the temperature uniformity to a greater extent than in a cases where the cooling plate 3 is disposed on the side of the wafer placement surface as shown in FIG. 1.

Furthermore, as shown in FIG. 3, the wafer holder of the present invention may have a heat conducting member 8 between the heating plate 2 and cooling plate 3. Since the heat conducting member 8 has the effect of suppressing fluctuations in the temperature, variations in the temperature caused by the heating means of the heating plate 2 and the cooling means of the cooling plate 3 can be ameliorated, so that the temperature of a wafer holder 1c can be controlled to a specified temperature in a short time, thus allowing a great improvement in the temperature uniformity of the wafer placement surface. Generally, metals such as copper, aluminum or the like, or alloys of the same, or ceramics such as aluminum nitride, silicon carbide or the like, can be used as the heat conducting member 8. This heat conducting member 8 will be described in detail later.

A material with a high thermal capacity is desirable as the material of the heat conducting member. The reason for this is that since such materials have an improved effect in suppressing fluctuations in the temperature of the wafer holder when a wafer is carried, the temperature of the semiconductor wafer can be controlled to a prescribed temperature in a short time. The easiest method of improving the thermal capacity is to increase the volume; impractical terms, however, it is difficult to increase the volume because of design restrictions. Accordingly, it is important to increase the thermal capacity per unit volume, and this thermal capacity per unit volume can be expressed as the product of the specific heat and density.

Considering the temperature control characteristics of the semiconductor wafer, it is desirable that the product of the specific heat and density of the heat conducting member be 2.0 J/cm³K or greater. For example, silicon carbide can be used as the material of the heat conducting member in this case. It is even more desirable if the product of the specific heat and density is 2.3 J/cm³K or greater; in this case, an aluminum alloy such as 5052 or the like, pure aluminum, aluminum nitride or the like can be used as the material of the heat conducting member. Furthermore, in cases where the product of the specific heat and density is set at 3.0 J/cm³K or greater, the temperature control characteristics of the semiconductor wafer are further improved if, for example, pure copper is used as the material of the heat conducting member.

Not only the coil-form heat generating body 6 shown in FIGS. 1 through 3, but also, for example, a film-form/foil-form heat generating body 9 such as a metallized thin film or metal foil of the type used in a wafer holder id shown in FIG. 4 can also be used as the heating means of the heating plate in the wafer holder of the present invention. Compared to the coil-form heat generating body 6, the film-form/foil-form heat generating body 9 allows the design of a more precise heat generation density distribution. Accordingly, temperature variations caused by the cooling means can be precisely canceled out, so that the uniformity of the temperature of the wafer placement surface can be greatly improved.

In cases where long-term reliability is considered important, a metallized thin film can be used as this film-form/foil-form heat generating body. In cases where cost is considered important, it is desirable to use a metal foil. If heat resistance is taken into account, then tungsten, molybdenum, tantalum or the like is desirable as the material of the metallized thin film. Furthermore, in regard to the material of the metal foil, since a structure is used in which circuits are formed by etching or the like and clamped by ceramic substrates, this material can be appropriately selected with consideration given to the matching of the coefficient of thermal expansion with the ceramic substrates. If cost and reliability are taken into account, a metal foil made of stainless steel or nickel is desirable.

It is desirable that the ceramic substrate that forms the heating plate have a high thermal conductivity. The reason for this is that this results in an improvement in the response characteristics of the heating means to variations in the temperature of the semiconductor wafer and the uniformity of the temperature of the wafer holder. For example, considering the response characteristics and uniformity of the temperature, it is desirable that the thermal conductivity of the ceramic substrate be 30 W/mK or greater. In this case, for example, aluminum oxide can be used as the material of the ceramic substrate. A thermal conductivity of 50 W/mK or greater is even more desirable for the ceramic substrate. In this case, for example, silicon carbide can be used. Furthermore, a thermal conductivity of 150 W/mK or greater is even more desirable. In this case, for example, aluminum nitride can be used. Also, it is desirable to use aluminum nitride because the contamination of the wafer is low and the reliability is high, in addition to high response characteristics and temperature uniformity.

Meanwhile, as is shown for example in FIGS. 1 through 4, the cooling plate of the wafer holder of the present invention is generally a plate in which the coolant passage 7 having a prescribed shape used to allow the flow of a coolant is disposed inside a metal substrate having a high thermal conductivity such as a substrate made of an aluminum alloy or the like. For example, grooves are formed in the surfaces of two metal substrates, metal pipes with a high thermal conductivity made of copper or a copper alloy are fitted into the grooves on one side, the pipes are then covered by the other metal substrate, and the other metal substrate is fastened in place by screw fastening or the like, so that the metal pipes are sealed inside. Furthermore, the coolant used in the present invention may be a coolant that has conventionally been used in such applications, for example, a Galden coolant may be appropriately used.

Furthermore, in the wafer holder of the present invention, a well known Peltier element can be used as the cooling means installed in the cooling plate. For example, in a wafer holder 1e shown in FIG. 5, the wafer holder has a plurality of Peltier elements 10 as part of the cooling plate 3, and each Peltier element 10 contacts the heat conducting member 8 at the other end thereof. As a result of the Peltier elements 10 thus being provided as the cooling means, the cooling capacity of the cooling plate is improved. Therefore, the temperature of the wafer placement surface can be controlled to the target temperature in a shorter time.

Temperature control of the wafer holder can be accomplished using either the cooling means or the heating means. However, since the temperature control characteristics of the wafer holder and wafer are superior in cases where the heating means is used, it is preferable to use the heating means to control the temperature. Specifically, compared to the cooling means using a coolant or the cooling means using a Peltier element, the heating means using a resistance heat generating body or the like generally show a superior response to control input. Accordingly, it is preferable for the cooling means to continuously cool the cooling plate and the heat conducting member with a constant output, and for the temperature to be controlled by the heating means on the basis of the temperature measured by the temperature measurement means.

Furthermore, it is desirable that the position of the temperature measurement means be close to the wafer placement surface. The reason for this is that this improves the response of the wafer holder to variations in the temperature of the wafer. Considering the response performance, it is desirable that the temperature measurement means 4 be disposed closer to the wafer placement surface than the cooling plate 3 or the Peltier elements 10 (for example, inside the heat conducting member 8) as in a wafer holder 1f shown in FIG. 6. Furthermore, if the temperature measurement means 4 is installed close to the wafer placement surface, and the distance between the temperature measurement means 4 and the heating plate 2 is set at L/2 or less with respect to the thickness L of the heat conducting member 8 as shown in FIG. 7, the response of a wafer holder 1g is even further improved. In particular, extremely high response characteristics can be obtained if the temperature measurement means 4 contacts the heating plate 2 as in a wafer holder 1h shown in FIG. 8.

In regard to the heating means of the heating plate, it is necessary to pay attention to the planarity and the surface roughness of the heat conducting member. The reason for this is that the planarity and the surface roughness of the heat conducting member have an effect on the thermal resistance of the contact interfaces with the heating plate and the cooling plate (including the Peltier elements) stacked on both sides, and consequently have an effect on the control characteristics of the wafer temperature. The planarity of the heat conducting member is preferably set at 30 μm or less, and is even more preferably set at 10 μm or less. Furthermore, in regard to the surface roughness of the heat conducting member, the Ra value is preferably 3 μm or less, and is even more preferably 1 μm or less.

The thermal resistance at the contact interfaces between the heating plate, the heat conducting member and the cooling plate (including the Peltier elements) is a sufficiently low value when the respective members are simply installed, if the values of the planarity and the surface roughness of these members are relatively small. However, the respective members are preferably pressed into contact in order to lower the thermal resistance at the contact interfaces between the respective members and thus improve the control characteristics of the wafer temperature. However, if the members are pressed into contact, there may be cases where the wafer holder is deformed or damaged because of differences in the coefficient of thermal expansion between the respective members.

The most effective means of eliminating such deformation or damage of the wafer holder is to set the temperature at the time of assembly of the wafer holder and the temperature during operation of the wafer holder close to each other, i.e., to set the control temperature of the wafer holder close to room temperature. If the target temperature of the temperature control of the wafer holder is set between 10 and 40° C., there is no deformation or damage caused by differences in the coefficient of thermal expansion between the respective members even if the respective members are pressed into contact. If the thermal resistance at the contact interfaces, reliability, cost and the like are taken into consideration, screw fastening is the simplest and most desirable means of pressing the respective members into contact.

In the wafer holder of the present invention, it is desirable that the semiconductor wafers be mounted on the wafer placement surface so that the wafers are separated from the wafer placement surface in the conventional manner. Although the semiconductor wafer is illustrated as if it directly contacts the wafer placement surface of the wafer holder in FIGS. 1 to 9, in the wafer holder of the present invention, it is desirable in reality that the semiconductor wafers be mounted on the wafer placement surface so that the wafers are separated from the wafer placement surface in the conventional manner. If the semiconductor wafers and wafer placement surface are in direct contact with each other, there is deterioration in the temperature uniformity of the semiconductor wafers, and contamination of the semiconductor wafers tends to occur.

As described above, the heating plate can be precisely designed compared to the cooling plate. Accordingly, the heating plate is conversely an important element for determining the temperature uniformity of the semiconductor wafers. Below, the method used to manufacture the heating plate will be described in detail, using as an example a case in which an aluminum nitride substrate (which is the most suitable as the heating plate) is used as the ceramic substrate that forms the heating plate, and the heat generating body of a metallized thin film is used as the heating means.

A powder with a specific surface area of 2.0 to 5.0 m²/g is desirable as the raw material powder of the aluminum nitride. If the specific surface area is less than 2.0 m²/g, there is a drop in the sintering properties of the aluminum nitride. On the other hand, if the specific surface are exceeds 5.0 m²/g, aggregation of the powder becomes extremely strong, so that handling becomes difficult. The amount of oxygen contained in the raw material powder is preferably 2 wt % (weight percent) or less. If the oxygen content is more than 2 wt %, the thermal conductivity of the sinter drops. Furthermore, the content of metal impurities other than aluminum contained in the raw material powder is preferably 2000 ppm or less. If this limit is exceeded, the thermal conductivity of the sinter drops. In particular, group IV elements such as Si and the like, and iron group elements such as Fe and the like have a considerable effect as metal impurities in lowering the thermal conductivity of the sinter. Accordingly, it is desirable that the content of such elements be 500 ppm or less.

Since aluminum nitride is a material that is difficult to sinter, it is desirable to add a sintering aid to the raw material aluminum nitride powder. Rare earth element compounds are desirable as sintering aids. Rare earth element compounds react with the aluminum oxide or aluminum oxide nitride present on the surfaces of the aluminum nitride powder particles in the sinter, and thus promote an increase in the density of the aluminum nitride. Furthermore, rear earth element compounds have the effect of removing oxygen that causes a drop in the thermal conductivity of the aluminum nitride sinter, so that the thermal conductivity of the aluminum nitride sinter that is obtained can be improved. Among rare earth element compounds, yttrium compounds which have a conspicuous effect in removing oxygen are especially desirable.

The amount of the abovementioned sintering aid that is added is preferably 0.01 to 5 wt %. If the amount added is less than 0.01 wt %, it is difficult to obtain a dense sinter, and the thermal conductivity of the sinter drops. On the other hand, if the amount added exceeds 5 wt %, the sintering aid is present at the grain boundaries of the aluminum nitride sinter, and thus, in the case of use in a corrosive atmosphere, the sintering aid present at the grain boundaries is etched, resulting in the loss of grains and particles. Furthermore, the amount of sintering aid added is even more preferably 1 wt % or less. In this case, since the sintering aid is not present even in the triple points of the grain boundaries, the corrosion resistance is improved.

Furthermore, oxides, nitrides, fluorides, stearic acid compounds and the like can be used as rare earth element compounds. Among these, oxides are inexpensive and easily obtainable, and are therefore desirable. Furthermore, stearic acid compounds have a high affinity with organic solvents, and thus, in cases where the raw material aluminum nitride powder, sintering aid and the like are mixed using an organic solvent, such compounds are desirable in terms of a high miscibility.

In the manufacturing process of the heating plate, specified amounts of an organic solvent, organic binder, and (if necessary) a dispersing agent or deflocculant are added to the abovementioned raw material aluminum nitride powder and sintering aid powder, and are mixed to produce a raw material slurry. Ball mill mixing, mixing using ultrasound or the like may be used as the mixing method. An aluminum nitride sinter can be obtained by molding and sintering the slurry thus obtained. Two types of methods, i.e., the co-firing method and the post metallizing method, may be used.

First, the post metallizing method will be described. The granules are manufactured from the abovementioned slurry using a spray drier or the like. These granules are introduced into a metal mold, and are subjected to press molding. It is desirable that the pressing pressure in this case be 9.8 MPa or greater. If the pressure is less than 9.8 MPa, a sufficient molding strength cannot be obtained in most cases, so that damage tends to occur during handling and the like.

Furthermore, the density of the molded article varies according to the binder content and the amount of sintering aid that is added. Ordinarily, however, it is desirable that this density be in the range of 1.5 to 2.5 g/cm³. If the density of the molded article is less than 1.5 g/cm³, the distance between the particles of the raw material powder is relatively large, and thus, Wintering tends not to proceed. On the other hand, if the density of the molded article exceeds 2.5 g/cm³, it becomes difficult to achieve sufficient removal of the binder inside the molded article in the degreasing treatment of the subsequent process. As a result, it becomes difficult to obtain a dense sinter by sintering.

The molded article that is obtained is subjected to a degreasing treatment by being heated in a non-oxidizing atmosphere. Nitrogen or argon is desirable as the gas of the non-oxidizing atmosphere. The heating temperature of the degreasing treatment is preferably 500 to 1000° C. If this temperature is less than 500° C., the binder cannot be sufficiently removed, so that an excessive amount of carbon remains in the molded article following the degreasing treatment. As a result, the sintering in the subsequent sintering process is impeded. On the other hand, if this temperature exceeds 1000° C., the amount of remaining carbon is too small. In such case, there is a drop in the capacity to remove oxygen from the oxide coating that is present on the surfaces of the aluminum nitride powder particles, so that the thermal conductivity of the sinter drops.

Furthermore, if a degreasing treatment is performed in an oxidizing atmosphere such as the atmosphere or the like, the surfaces of the aluminum nitride powder particles are oxidized, so that the thermal conductivity of the sinter drops. Furthermore, it is desirable that the amount of carbon remaining in the molded article following the degreasing treatment be 1.0 wt % or less. The reason for this is that if carbon in excess of 1.0 wt % remains in the molded article, sintering is impeded so that a dense sinter cannot be obtained.

The molded article following degreasing is sintered, thus producing an aluminum nitride sinter. This sintering is performed at a temperature of 1700 to 2000° C. in a non-oxidizing atmosphere of nitrogen, argon or the like. It is desirable that the moisture contained in the gas of the non-oxidizing atmosphere such as nitrogen or the like that is used during sintering be −30° C. or less in terms of dew point. In cases where the moisture content is greater than this, the aluminum nitride may react with the moisture in the atmosphere gas during sintering, so that there is a possibility that the thermal conductivity may be caused to drop by oxide nitrides that are formed. Furthermore, it is desirable that the amount of oxygen in the atmosphere gas be 0.001 vol % or less. If the oxygen content exceeds this amount, there is a possibility that the surfaces of the aluminum nitride particles will be oxidized, so that the thermal conductivity drops.

Furthermore, the jig that is used during sintering is ideally a boron nitride (BN) molded article. Such a BN molded article has a sufficient heat resistance against the abovementioned sintering temperature, and has solid lubricating properties on the surface. Accordingly, friction between the jig and the molded article that contracts during sintering can be reduced, so that a sinter with little strain can be obtained.

The aluminum nitride sinter thus obtained is worked if necessary to form a substrate. In cases where a conductive paste is applied by screen printing in a subsequent process, it is desirable that the surface roughness Ra of the sinter substrate be 5 μm or less. If the surface roughness Ra exceeds 5 μm, the circuit pattern tends to run and defects such as pinholes and the like tend to be generated when a circuit is formed by screen printing. The surface roughness Ra of the substrate is even more preferably 1 μm or less.

In cases where the sinter is polished in order to obtain the abovementioned surface roughness, it is desirable that the surface on the opposite side also be polished along with the surface on which screen printing is performed. In cases where only the surface on which screen printing is performed is polished, the sinter substrate is supported on the opposite side (which is not polished) when screen printing is performed. In this case, since protrusions and foreign matter may be present on the unpolished surface, the fastening of the sinter substrate becomes unstable, so that problems may occur in circuit pattern formation in screen printing.

In regard to the polished sinter substrate, it is desirable that the parallelism of the worked surfaces be 0.5 mm or less, and the parallelism of 0.1 mm or less is especially desirable. The planarity of the screen-printed surface is preferably 0.5 mm or less, and the planarity of 0.1 mm or less is particularly desirable. The reason for this is because if the parallelism of the worked surfaces is greater than 0.5 mm, or if the planarity of the printed surface is greater than 0.5 mm, there may be an increase in the variation in the thickness of the conductive paste.

The surface of the aluminum nitride sinter substrate thus obtained is coated with a conductive paste by screen printing, thus forming a prescribed circuit pattern. The conductive paste that is used can be obtained by mixing a metal powder, and (if necessary) an oxide powder, an organic binder and an organic solvent. From the standpoint of matching the coefficient of thermal expansion with the ceramic, it is desirable to use tungsten, molybdenum or tantalum as the metal powder.

Furthermore, an oxide powder may also be added to the conductive paste in order to increase the adhesive strength with the aluminum nitride sinter substrate. An oxide of a group IIa element or group IIIa element, Al₂O₃, SiO₂ or the like is desirable as the oxide powder that is added. In particular, indium oxide is especially desirable, since this compound shows extremely good wetting with respect to aluminum nitride. The amount of such oxides added is preferably 0.1 to 30 wt %. If the amount of oxides added is less than 0.1 wt %, the adhesive strength of the metallized thin film of the heat generating body that is formed and the aluminum nitride sinter substrate drops. On the other hand, if this amount exceeds 30 wt %, the electrical resistance value of the metallized thin film of the heat generating body is high.

It is desirable that the thickness of the conductive paste be 5 to 100 μm in terms of the thickness after drying. In cases where this thickness is less than 5 μm, the electrical resistance value of the metallized thin film that is obtained becomes excessively high, and the adhesive strength with the substrate also drops. Furthermore, the adhesive strength with the substrate also drops in cases where this thickness exceeds 100 μm. Furthermore, it is desirable that the spacing of the circuit patterns formed by the conductive paste be 0.1 mm or greater. If this spacing is less than 0.1 mm, a leakage current is generated by the applied voltage and temperature when current is caused to flow through the heat generating body, so that short-circuiting occurs. Especially in cases where high reliability is required, it is desirable to set the pattern spacing at 1 mm or greater, and a spacing of 3 mm or greater is even more desirable.

The conductive paste thus applied by screen printing is calcined following degreasing of the conductive paste, so that a metallized thin film is formed. It is desirable that the degreasing treatment be performed in a non-oxidizing atmosphere of nitrogen, argon or the like, and that the degreasing temperature be 500° C. or greater. If the degreasing temperature is less than 500° C., removal of the organic binder from the conductive paste is insufficient, so that carbon remains in the metallized thin film. Consequently, metal carbides are formed in the subsequent firing so that the electrical resistance value of the metallized thin film constituting the heat generating body rises.

Furthermore, calcining is preferably performed at a temperature of 1500° C. or greater in a non-oxidizing atmosphere of nitrogen, argon or the like. If the temperature is less than 1500° C., particle growth of the metal powder in the conductive paste does not proceed, and thus, the electrical resistance value of the metallized thin film following firing is excessively high. Furthermore, it is desirable that the firing temperature not exceed the sintering temperature of the ceramic used, such as aluminum nitride or the like. If the conductive paste is calcined at a temperature that exceeds the sintering temperature of the ceramic, the sintering aid and the like contained in the ceramic will begin to volatilize, and particle growth of the metal powder in the conductive paste will be promoted so that the adhesive strength between the ceramic and metallized thin film will drop.

An insulating coating can be formed on top of the metallized film that is formed in order to ensure the insulating properties of this metallized film.

There are no particular restrictions on the material of this insulating coating, as long as this material shows little reactivity with the heat generating body, and as long as the difference in the coefficient of thermal expansion with the aluminum nitride is 5.0×10⁻⁶/K or less. For example, crystallized glass, aluminum nitride or the like can be used. For example, an insulating coating is obtained by preparing such materials in the form of a paste, applying the paste to a specified thickness on the metallized thin film by screen printing, performing a degreasing treatment if necessary, and then firing this coating at a specified temperature.

If necessary, furthermore, a ceramic substrate such as aluminum nitride or the like can be layered on the abovementioned metallized thin film or insulating coating. This covering with a ceramic substrate is preferably performed via a bonding agent. A preparation prepared by adding a IIa group element compound or IIIa group element compound and a binder and solvent to an aluminum oxide powder or aluminum nitride powder, and forming this mixture into a paste, is used as a bonding agent. There are no particular restrictions on the thickness of the bonding agent that is applied to the joining surface by a method such as screen printing or the like. However, it is desirable that this thickness be 5 μm or greater. The reason for this is that if the thickness is less than 5 μm, bonding defects such as pinholes in the bonding layer, irregular bonding and the like tend to occur.

The ceramic substrate coated with a bonding agent is subjected to a degreasing treatment at a temperature of 500° C. or greater in a non-oxidizing atmosphere. Afterward, the two layered ceramic substrates are superimposed with the metallized thin film or insulating coating on the inside, a specified load is applied, and the ceramic substrates are joined to each other by heating in a non-oxidizing atmosphere. It is desirable that the load applied be 5 kPa or greater. If this load is less than 5 kPa, a sufficient bonding strength cannot be obtained, or the abovementioned bonding defects tend to be generated.

Furthermore, there are no particular restrictions on the heating temperature used for bonding as long as this temperature is a temperature that causes sufficient adhesion of the ceramic substrates to each other via the bonding layer. However, it is desirable that this temperature be 1500° C. or greater. If the bonding temperature is less than 1500° C., it is difficult to obtain a sufficient bonding strength, and bonding defects tend to occur. Furthermore, it is desirable to use nitrogen, argon or the like as the non-oxidizing atmosphere during the abovementioned degreasing and bonding. In this way, a heating plate with a metallized thin film heat generating body can be obtained as a heating means inside the aluminum nitride substrates which are ceramic substrates.

Furthermore, in cases where a coil-form heat generating body is used as a heating means, this can be manufactured by placing a coil made of molybdenum or the like inside the abovementioned aluminum nitride raw material powder, and using a hot pressing method. The hot pressing temperature and atmosphere may be the same as the sintering temperature and atmosphere used for the abovementioned aluminum nitride. However, it is desirable that the hot pressing pressure be set at 0.98 MPa or greater. If the hot pressing pressure is less than 0.98 MPa, gaps may be created between the coil and the aluminum nitride powder, so that the performance of the wafer holder that is ultimately obtained may drop.

Next, the manufacture of a heating plate by the co-firing method will be described. Using the raw material slurry described above, a sheet is formed by the doctor blade method. Although there are no particular restrictions on this sheet formation, it is desirable that the thickness of the sheet after drying be 3 mm or less. The reason for this is that if the thickness of the sheet exceeds 3 mm, the amount of drying shrinkage of the slurry is increased, so that there is a high probability that cracking will occur in the sheet.

The sheet that is obtained is coated with the same conductive paste as that described above by a method such as screen printing or the like, so that a prescribed circuit pattern is formed. The conductive paste that is used may be the same as that described above in the abovementioned post-metallizing method. However, in the co-firing method, an oxide powder may not need to be added to the conductive paste.

A separate sheet on which no circuit pattern is formed is layered on the circuit formation surface of the sheet on which a circuit has thus been formed. More specifically, one sheet is coated with a solvent if necessary, and both sheets are set in specified positions and superimposed. In this state, heating is performed if necessary. However, it is desirable that the heating temperature be 150° C. or less. The reason for this is that if heating is performed to a temperature exceeding this value, the layered sheets will undergo extensive deformation. Subsequently, pressure is applied to the two layered sheets so that the sheets are integrated. The pressure that is applied is preferably in the range of 1 to 100 MPa. If the pressure is less than 1 MPa, the sheets may not be sufficiently integrated, so that peeling may occur in subsequent processes. On the other hand, if a pressure exceeding 100 MPa is applied, the amount of deformation of the sheets will be excessive.

These layered sheets are subjected to a degreasing treatment and sintering in the same manner as in the abovementioned post-metallizing method. As a result, the circuit of the applied conductive paste can be converted into a metallized thin film, and the sheets can be sintered. The degreasing treatment, sintering temperature, amount of carbon and the like are the same as in the case of the post-metallizing method. In this way, a heating plate which has a metallized thin film constituting a heating means inside a ceramic substrate made of aluminum nitride or the like can be obtained.

Furthermore, in cases where the metallized thin film constituting the heating means is formed so that this film is exposed on the outermost layer of the ceramic substrate made of aluminum nitride or the like, an insulating coating can be formed on top of the metallized thin film constituting the heating means in the same manner as in the case of the abovementioned post-metallizing method in order to protect the heating means constituting a heat generating body and in order to ensure insulating properties.

The wafer holder of the present invention described above makes it possible to achieve a precisely uniform temperature of the wafer placement surface over the entire area of this surface in a short time. Accordingly, the temperature of the semiconductor wafer on the wafer placement surface can also be made precisely uniform over the entire area of the wafer in a short time. In an exposure apparatus using this wafer holder that is superior in terms of temperature uniformity, the semiconductor wafer can be uniformly heated so that thermal expansion is prevented and deviation in the exposure position is eliminated. Accordingly, the throughput can be improved, and the formation of fine circuits can be handled.

### WORKING EXAMPLES

### Working Example 1

The wafer holder 1a shown in FIG. 1 was manufactured. First, a plate of aluminum alloy 5052 having a diameter of 300 mm and a thickness of 13 mm was prepared, a groove having a width of 8 mm and a depth of 8 mm was worked in the PDC 200 mm position of this plate, and a copper pipe with an external diameter of 8 mm serving as a coolant passage was inserted into this groove. A separate plate of aluminum alloy 5052 having a diameter of 300 mm and a thickness of 5 mm was superimposed so that this copper pipe was sealed, and this plate was fastened in place by screw fastening, thus producing a cooling plate 3 having a copper pipe coolant passage 7 as an internal cooling means as shown in FIG. 10.

Meanwhile, using aluminum oxide (Al₂O₃) as the ceramic substrate material, a heating plate 2 having a molybdenum coil as the coil-form heat generating body 6 of the heating means was manufactured. Specifically, the size of the substrate was set at a diameter of 300 mm and a thickness of 7 mm, and a coil-form heat generating body 6 was sealed inside the substrate using a hot pressing method. Both surfaces of the sinter thus obtained were polished, thus adjusting the surface roughness Ra to 4 μm, the degree of parallelism to 0.2 mm, and the planarity to 0.2 mm. Furthermore, the molybdenum coil of the coil-form heat generating body 6 was designed so that this coil was disposed in a concentrated manner directly beneath the coolant passage 7 at the time of layering with the cooling plate 3.

The abovementioned cooling plate 3 and the heating plate 2 were disposed and layered so that the cooling plate 3 was merely placed on top of the heating plate 2. Furthermore, the upper surface of this cooling plate 3 was used as the wafer placement surface, and the wafer holder 1a was completed by pasting a resistance temperature detector (RTD) to the center of the back surface of the heating plate 2 to form the temperature measurement means 4. Galden was used as the coolant in the coolant passage 7 constituting the cooling means, and the Galden temperature was controlled so that the temperature measured by the temperature measurement means was maintained at 25° C. On the other hand, the output of the coil-form heat generating body 6 of the heating plate 2 was fixed regardless of the value measured by the temperature measurement means 4.

As shown in FIG. 11, the temperature distribution of the semiconductor wafer carried on the wafer placement surface of the wafer holder 1a was measured using a wafer temperature gauge 15 in which resistance temperature detectors (RTD) 14 were embedded in 17 places in a silicon semiconductor wafer 5 having a diameter of 300 mm. Specifically, the wafer temperature gauge 15 maintained at a temperature of 30° C.±0.5° C. was placed on the wafer placement surface of the wafer holder 1a set to and maintained at 25° C. as described above (as measured by the temperature measurement means 4), and measurements were taken of the minimum temperature and the maximum temperature of the wafer temperature gauge 15 after 7 seconds had elapsed following this placement.

These measurements were repeated 10 times, and the mean values of the minimum temperature and the maximum temperature were determined. In this case, the mean minimum temperature was 24.14° C., and the mean maximum temperature was 25.81° C., and thus, the deviation from the set temperature of 25° C. was 0.86° C.

### Comparative Example 1

The common conventional wafer holder 11 shown in FIG. 9 was manufactured. First, a temperature adjustment plate 12 comprising both cooling means and heating means was manufactured. Specifically, groove working was performed in the same manner as in Working Example 1 in an aluminum alloy plate having a diameter of 300 mm and a thickness of 13 mm, and a copper pipe was inserted to form a coolant passage 7. Furthermore, groove working was formed in the same aluminum alloy plate, and a molybdenum coil with an insulating coating constituting a coil-form heat generating body 6 was inserted. Then, a separate aluminum alloy plate having a diameter of 300 mm and a thickness of 5 mm was fastened from above by screw fastening, thus producing a temperature adjustment plate 12. Furthermore, the coil-form heat generating body 6 was disposed in a concentrated manner in the vicinity of the coolant passage 7, and the system was designed so that both of these parts were disposed on the same plane.

Meanwhile, an aluminum oxide substrate 13 having a diameter of 300 mm and a thickness of 7 mm was prepared, and both sides of this substrate were polished so that the surface roughness Ra was adjusted to 4 μm, the degree of parallelism to 0.2 mm, and the planarity to 0.2 mm. This aluminum oxide substrate 13 and the abovementioned temperature adjustment plate 12 were disposed and layered so that the temperature adjustment plate 12 was merely placed on top of the aluminum oxide substrate 13. Furthermore, a resistance temperature detector (RTD) was pasted to the center of the back surface of the aluminum oxide substrate 13 to form temperature measurement means 4, thus completing the conventional wafer holder 11.

Galden was used as the coolant in the coolant passage 7 constituting the cooling means, and the Galden temperature was controlled so that the temperature measured by the temperature measurement means was maintained at 25° C. Meanwhile, the output of the coil-form heating body 6 of the heating plate 2 was fixed regardless of the value measured by the temperature measurement means 4. When the minimum temperature and the maximum temperature of the wafer temperature gauge 15 were measured in the same manner as in Working Example 1, the mean minimum temperature was 23.98° C., and the mean maximum temperature was 25.95° C., and thus, the deviation from the set temperature was 1.02° C.

### Working Example 2

The wafer holder 1b shown in FIG. 2 was manufactured. Specifically, a cooling plate 3 and heating plate 2 were manufactured in the same manner as in Working Example 1. The coil-form heat generating body 6 comprising a molybdenum coil was designed so that this coil was disposed in a concentrated manner directly above the coolant passage 7 when the heating plate 2 is stacked on top of the cooling plate 3. The parts were disposed and layered so that the heating plate 2 was on top of the cooling plate 3. The wafer holder 1b was then completed by pasting a resistance temperature detector (RTD) to the center of the back surface of the cooling plate 3 to form temperature measurement means 4.

In the wafer holder 1b thus obtained, Galden was used as the coolant of the cooling means, and the Galden temperature was controlled so that the temperature measured by the temperature measurement means 4 was maintained at 25° C. Meanwhile, the output of the coil-form heat generating body 6 of the heating plate 2 was fixed regardless of the value measured by the temperature measurement means 4.

When the minimum temperature and the maximum temperature of the wafer temperature gauge 15 were measured in the same manner as in Working Example 1, the mean minimum temperature was 24.29° C., and the mean maximum temperature was 25.76° C., and thus, the deviation from the set temperature was 0.76° C.

### Working Example 3

The wafer holder 1c shown in FIG. 3 was manufactured. A cooling plate 3 and heating plate 2 were manufactured in the same manner as in the abovementioned Working Example 2. Furthermore, a plate of aluminum alloy 5052 having a diameter of 300 mm and a thickness of 13 mm was prepared, and this plate was polished so that the surface roughness Ra was adjusted to 5 μm and the planarity to 40 μm, thus producing a heat conducting member 8.

These parts were disposed and layered in the order of the cooling plate 3, the heat conducting member 8 and the heating plate 2 from the bottom, and the wafer holder 1c was completed by pasting a resistance temperature detector (RTD) to the center of the back surface of the cooling plate 3 as the temperature measurement means 4.

In the wafer holder 1c thus obtained, Galden was used as the coolant of the cooling means, and the Galden temperature was controlled so that the temperature measured by the temperature measurement means 4 was maintained at 25° C. Meanwhile, the output of the coil-form heat generating body 6 of the heating plate 2 was fixed regardless of the value measured by the temperature measurement means 4.

When the minimum temperature and the maximum temperature of the wafer temperature gauge 15 were measured in the same manner as in Working Example 1, the mean minimum temperature was 24.39° C., and the mean maximum temperature was 25.67° C., and thus, the deviation from the set temperature was 0.67° C.

### Working Example 4

The wafer holder 1c shown in FIG. 3 was manufactured in the same manner as in the abovementioned Working Example 3. However, Galden was used as the coolant of the cooling means, and the Galden temperature was controlled to a fixed value regardless of the temperature measured by the temperature measurement means 4. Meanwhile, the output of the coil-form heat generating body 6 of the heating plate 2 was controlled so that the temperature measured by the temperature measurement means 4 was maintained at 25° C.

When the minimum temperature and the maximum temperature of the wafer temperature gauge 15 were measured in the same manner as in Working Example 1, the mean minimum temperature was 24.42° C., and the mean maximum temperature was 25.51° C., and thus, the deviation from the set temperature was 0.58° C.

### Working Example 5

The wafer holder id shown in FIG. 4 was manufactured. Specifically, a heating plate 2 was manufactured using aluminum oxide as the substrate material. As the film-form/foil-form heat generating body 9 constituting the heating means, a metallized thin film was formed by the post-metallizing method using a conductive paste of tungsten as the metal powder. The metallized thin film was designed so that this film was disposed in a concentrated manner directly above the coolant passage 7 at the time of layering with the cooling plate 3.

Except for the use of the abovementioned heating plate 2, this manufacturing process was performed in the same manner as in the abovementioned Working Example 4. Specifically, these parts were disposed and layered in the order of the cooling plate 3, the heat conducting member 8 and the heating plate 2 from the bottom, and the wafer holder id was completed by pasting a resistance temperature detector (RTD) to the center of the back surface of the cooling plate 3 as the temperature measurement means 4.

In the same manner as in the abovementioned Working Example 4, the temperature of the coolant on the side of the cooling plate 3 was fixed, while the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.50° C., and the mean maximum temperature was 25.45° C., and thus, the deviation from the set temperature was 0.50° C.

### Working Example 6

The wafer holder 1d shown in FIG. 4 was manufactured in the same manner as in the abovementioned Working Example 5. Specifically, aluminum oxide was used as the material of the substrate, and a stainless steel foil formed by etching was used as the film-form/foil-form heat generating body 9 constituting the heating means. The stainless steel foil was designed so that this foil was disposed in a concentrated manner directly above the coolant passage 7 when layered with the cooling plate 3. The size of the substrate was a diameter of 300 mm and a thickness of 7 mm, and the stainless steel foil was sealed inside the substrate by hot pressing.

Except for the abovementioned heating plate 2, the manufacturing process was the same as in the abovementioned Working Example 4. Specifically, these parts were disposed and layered in the order of the cooling plate 3, the heat conducting member 8 and the heating plate 2 from the bottom, and the wafer holder 1d was completed by pasting a resistance temperature detector (RTD) to the center of the back surface of the cooling plate 3 as the temperature measurement means 4.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.49° C., and the mean maximum temperature was 25.46° C., and thus, the deviation from the set temperature was 0.51° C.

### Working Example 7

The wafer holder 1e shown in FIG. 5 was manufactured. Specifically, the heating plate 2 was manufactured in the same manner as in Working Example 5. The metallized thin film was designed so that this film was disposed in a concentrated manner directly above the Peltier elements 10 when layered with the cooling plate 3. The cooling plate 3 was manufactured in the same manner as in Working Example 2, and the heat conducting member 8 was manufactured in the same manner as in Working Example 3.

The Peltier elements 10 were disposed on the cooling plate 3, and the heat conducting member 8 and the heating plate 2 were disposed and layered in that order. Then, the wafer holder 1e was completed by pasting a resistance temperature detector (RTD) to the center of the back surface of the cooling plate 3 as the temperature measurement means 4.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.58° C., and the mean maximum temperature was 25.37° C., and thus, the deviation from the set temperature was 0.42° C.

### Working Example 8

The wafer holder if shown in FIG. 6 was manufactured. Specifically, as in Working Example 7, the cooling plate 3, the Peltier elements 10, the heat conducting member 8 and the heating plate 2 were layered in that order, and the wafer holder if was completed by embedding a resistance temperature detector (RTD) in the vicinity of the undersurface of the heat conducting member 8 as the temperature measurement means 4.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.64° C., and the mean maximum temperature was 25.32° C., and thus, the deviation from the set temperature was 0.36° C.

### Working Example 9

The wafer holder 1g shown in FIG. 7 was manufactured. Specifically, as in Working Example 7, the cooling plate 3, the Peltier elements 10, the heat conducting member 8 and the heating plate 2 were layered in that order, and the wafer holder 1g was completed by embedding a resistance temperature detector (RTD) in the vicinity of the upper surface of the heat conducting member 8 (in a position which was such that the distance between the temperature measurement means 4 and the heating plate 2 was L/2 or less with respect to the thickness L of the heat conducting member 8) as the temperature measurement means 4.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.72° C., and the mean maximum temperature was 25.31° C., and thus, the deviation from the set temperature was 0.31° C.

### Working Example 10

The wafer holder 1h shown in FIG. 8 was manufactured. Specifically, as in Working Example 7, the cooling plate 3, the Peltier elements 10, the heat conducting member 8 and the heating plate 2 were layered in that order, and the wafer holder 1h was completed by embedding a resistance temperature detector (RTD) in the center of the contact surface between the heat conducting member 8 and the heating plate 2.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.74° C., and the mean maximum temperature was 25.22° C., and thus, the deviation from the set temperature was 0.26° C.

### Working Example 11

The wafer holder 1h shown in FIG. 8 was manufactured. Specifically, the structure is basically the same as Working Example 10 except that a plate of aluminum alloy 5052 having a diameter of 300 mm and a thickness of 13 mm was prepared as the heat conducting member 8, and this plate was polished so that the surface roughness Ra was adjusted to 5 μm, and the planarity to 25 μm.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.78° C., and the mean maximum temperature was 25.20° C., and thus, the deviation from the set temperature was 0.22° C.

### Working Example 12

The wafer holder 1h shown in FIG. 8 was manufactured. The structure is basically the same as Working Example 10, except that a plate of aluminum alloy 5052 having a diameter of 300 mm and a thickness of 13 mm was prepared as the heat conducting member 8, and this plate was polished so that the surface roughness Ra was adjusted to 5 μm, and the planarity to 8 μm.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.85° C., and the mean maximum temperature was 25.18° C., and thus, the deviation from the set temperature was 0.18° C.

### Working Example 13

The wafer holder 1h shown in FIG. 8 was manufactured. Specifically, the structure is basically the same as Working Example 10 except that a plate of aluminum alloy 5052 having a diameter of 300 mm and a thickness of 13 mm was prepared as the heat conducting member 8, and this plate was polished so that the surface roughness Ra was adjusted to 2.6 μm, and the planarity to 8 μm.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.87° C., and the mean maximum temperature was 25.14° C., and thus, the deviation from the set temperature was 0.14° C.

### Working Example 14

The wafer holder 1h shown in FIG. 8 was manufactured. The structure is basically the same as Working Example 10 except that a plate of aluminum alloy 5052 having a diameter of 300 mm and a thickness of 13 mm was prepared as the heat conducting member 8, and this plate was polished so that the surface roughness Ra was adjusted to 0.8 μm, and the planarity to 8 μm.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.90° C., and the mean maximum temperature was 25.11° C., and thus, the deviation from the set temperature was 0.11° C.

### Working Example 15

The wafer holder 1h shown in FIG. 8 was manufactured. This wafer holder was manufactured in the same manner as in the abovementioned Working Example 14 except that silicon nitride (Si₃N₄) was used as the substrate material of the heating plate 2.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.86° C., and the mean maximum temperature was 25.11° C., and thus, the deviation from the set temperature was 0.14° C.

### Working Example 16

The wafer holder 1h shown in FIG. 8 was manufactured. This wafer holder was manufactured in the same manner as in the abovementioned Working Example 14 except that silicon carbide (SiC) was used as the substrate material of the heating plate 2.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working. Example 1, the mean minimum temperature was 24.94° C., and the mean maximum temperature was 25.08° C., and thus, the deviation from the set temperature was 0.08° C.

### Working Example 17

The wafer holder 1h shown in FIG. 8 was manufactured. This wafer holder was manufactured in the same manner as in the abovementioned Working Example 14 except that aluminum nitride (AlN) was used as the substrate material of the heating plate 2.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and maximum temperature of the wafer temperature gauge 15 were measured in the same manner as in Working Example 1, the mean minimum temperature was 24.96° C., and the mean maximum temperature was 25.05° C., and thus, the deviation from the set temperature was 0.05° C.

### Working Example 18

The wafer holder 1h shown in FIG. 8 was manufactured. This wafer holder was manufactured in the same manner as in the abovementioned Working Example 17 except that silicon dioxide (quartz) was used as the material of the heat conducting member 8.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.91° C., and the mean maximum temperature was 25.07° C., and thus, the deviation from the set temperature was 0.09° C.

### Working Example 19

The wafer holder 1h shown in FIG. 8 was manufactured. This wafer holder was manufactured in the same manner as in the abovementioned Working Example 17 except that silicon carbide (SiC) was used as the material of the heat conducting member 8.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.93° C., and the mean maximum temperature was 25.05° C., and thus, the deviation from the set temperature was 0.07° C.

### Working Example 20

The wafer holder 1h shown in FIG. 8 was manufactured. This wafer holder was manufactured in the same manner as in the abovementioned Working Example 17 except that pure copper was used as the material of the heat conducting member 8.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 24.97° C., and the mean maximum temperature was 25.02° C., and thus, the deviation from the set temperature was 0.03° C.

### Working Example 21

The wafer holder 1h shown in FIG. 8 was manufactured. This wafer holder was manufactured in the same manner as in the abovementioned Working Example 20 except that pure copper was used as the material of the heat conducting member 8. Furthermore, the cooling plate 3, the Peltier elements 10, the heat conducting member 8 and the heating plate 2 were layered in that order, and the wafer holder 1h was then obtained by fastening the respective parts by screw fastening.

As in the abovementioned Working Example 4, the temperature of the coolant on the side of the cooling plate 3 was fixed, and the output on the side of the heating plate 2 was controlled so that the temperature measured by the temperature measurement means 4 was maintained at 25° C. When the minimum temperature and the maximum temperature of the wafer temperature gauge 15 were measured in the same manner as in Working Example 1, the mean minimum temperature was 25.00° C., and the mean maximum temperature was 25.01° C., and thus, the deviation from the set temperature was 0.01° C.

The structures of the wafer holders, the materials of the respective members and the wafer temperatures obtained are summarized in the following table for the abovementioned Working Examples 1 through 21 and Comparative Example 1.

TABLE

| | | Resistor | | | | | | |
|---|---|---|---|---|---|---|---|---|
| | | heat | | | | | | |
| | | generating | | | | | | |
| | | body | | | | | | |
| | | A: Mo coil | | | Substrate of | | Heat | |
| | | B: W | | Method | heating means | | conducting member | |
| | | metallized | Object | used to | | Thermal | | Surface |
| | | film | of | fasten | | conductivity | Planarity | roughness |
| | Structure | C: SUS foil | control | members | Material | W/mK | μm | μm |
| Working | FIG. 1 | A | Cooling | Mounting | Al₂O₃ | 30 | — | — |
| Example 1 | | | | | | | | |
| Comparative | FIG. 9 | A | Cooling | Mounting | Al₂O₃ | 30 | — | — |
| Example 1 | | | | | | | | |
| Working | FIG. 2 | A | Cooling | Mounting | Al₂O₃ | 30 | — | — |
| Example 2 | | | | | | | | |
| Working | FIG. 3 | A | Cooling | Mounting | Al₂O₃ | 30 | 40 | 5 |
| Example 3 | | | | | | | | |
| Working | FIG. 3 | A | Heating | Mounting | Al₂O₃ | 30 | 40 | 5 |
| Example 4 | | | | | | | | |
| Working | FIG. 4 | B | Heating | Mounting | Al₂O₃ | 30 | 40 | 5 |
| Example 5 | | | | | | | | |
| Working | FIG. 4 | C | Heating | Mounting | Al₂O₃ | 30 | 40 | 5 |
| Example 6 | | | | | | | | |
| Working | FIG. 5 | B | Heating | Mounting | Al₂O₃ | 30 | 40 | 5 |
| Example 7 | | | | | | | | |
| Working | FIG. 6 | B | Heating | Mounting | Al₂O₃ | 30 | 40 | 5 |
| Example 8 | | | | | | | | |
| Working | FIG. 7 | B | Heating | Mounting | Al₂O₃ | 30 | 40 | 5 |
| Example 9 | | | | | | | | |
| Working | FIG. 8 | B | Heating | Mounting | Al₂O₃ | 30 | 40 | 5 |
| Example 10 | | | | | | | | |
| Working | FIG. 8 | B | Heating | Mounting | Al₂O₃ | 30 | 25 | 5 |
| Example 11 | | | | | | | | |
| Working | FIG. 8 | B | Heating | Mounting | Al₂O₃ | 30 | 8 | 5 |
| Example 12 | | | | | | | | |
| Working | FIG. 8 | B | Heating | Mounting | Al₂O₃ | 30 | 8 | 2.6 |
| Example 13 | | | | | | | | |
| Working | FIG. 8 | B | Heating | Mounting | Al₂O₃ | 30 | 8 | 0.8 |
| Example 14 | | | | | | | | |
| Working | FIG. 8 | B | Heating | Mounting | Si₃N₄ | 24 | 8 | 0.8 |
| Example 15 | | | | | | | | |
| Working | FIG. 8 | B | Heating | Mounting | SiC | 65 | 8 | 0.8 |
| Example 16 | | | | | | | | |
| Working | FIG. 8 | B | Heating | Mounting | AlN | 173 | 8 | 0.8 |
| Example 17 | | | | | | | | |
| Working | FIG. 8 | B | Heating | Mounting | AlN | 173 | 8 | 0.8 |
| Example 18 | | | | | | | | |
| Working | FIG. 8 | B | Heating | Mounting | AlN | 173 | 8 | 0.8 |
| Example 19 | | | | | | | | |
| Working | FIG. 8 | B | Heating | Mounting | AlN | 173 | 8 | 0.8 |
| Example 20 | | | | | | | | |
| Working | FIG. 8 | B | Heating | Fastening | AlN | 173 | 8 | 0.8 |
| Example 21 | | | | with | | | | |
| | | | | screws | | | | |

| | | | | | Wafer surface | | |
|---|---|---|---|---|---|---|---|
| | Heat conducting member | | | | temperature ° C. | | |
| | | Specific | | Specific | Mean | Mean | Deviation |
| | | heat | Density | heat × density | minimum | maximum | from set |
| | Material | J/gK | g/cm³ | J/cm³K | temperature | temperature | temperature |
| Working | — | — | — | — | 24.14 | 25.81 | 0.86 |
| Example 1 | | | | | | | |
| Comparative | — | — | — | — | 23.98 | 25.95 | 1.02 |
| Example 1 | | | | | | | |
| Working | — | — | — | — | 24.29 | 25.76 | 0.76 |
| Example 2 | | | | | | | |
| Working | 5052 | 0.90 | 2.69 | 2.42 | 24.39 | 25.67 | 0.67 |
| Example 3 | | | | | | | |
| Working | 5052 | 0.90 | 2.69 | 2.42 | 24.42 | 25.51 | 0.58 |
| Example 4 | | | | | | | |
| Working | 5052 | 0.90 | 2.69 | 2.42 | 24.50 | 25.45 | 0.50 |
| Example 5 | | | | | | | |
| Working | 5052 | 0.90 | 2.69 | 2.42 | 24.49 | 25.46 | 0.51 |
| Example 6 | | | | | | | |
| Working | 5052 | 0.90 | 2.69 | 2.42 | 24.58 | 25.37 | 0.42 |
| Example 7 | | | | | | | |
| Working | 5052 | 0.90 | 2.69 | 2.42 | 24.64 | 25.32 | 0.36 |
| Example 8 | | | | | | | |
| Working | 5052 | 0.90 | 2.69 | 2.42 | 24.72 | 25.31 | 0.31 |
| Example 9 | | | | | | | |
| Working | 5052 | 0.90 | 2.69 | 2.42 | 24.74 | 25.22 | 0.26 |
| Example 10 | | | | | | | |
| Working | 5052 | 0.90 | 2.69 | 2.42 | 24.78 | 25.20 | 0.22 |
| Example 11 | | | | | | | |
| Working | 5052 | 0.90 | 2.69 | 2.42 | 24.85 | 25.18 | 0.18 |
| Example 12 | | | | | | | |
| Working | 5052 | 0.90 | 2.69 | 2.42 | 24.87 | 25.14 | 0.14 |
| Example 13 | | | | | | | |
| Working | 5052 | 0.90 | 2.69 | 2.42 | 24.90 | 25.11 | 0.11 |
| Example 14 | | | | | | | |
| Working | 5052 | 0.90 | 2.69 | 2.42 | 24.86 | 25.11 | 0.14 |
| Example 15 | | | | | | | |
| Working | 5052 | 0.90 | 2.69 | 2.42 | 24.94 | 25.08 | 0.08 |
| Example 16 | | | | | | | |
| Working | 5052 | 0.90 | 2.69 | 2.42 | 24.96 | 25.05 | 0.05 |
| Example 17 | | | | | | | |
| Working | SiO₂ | 0.72 | 2.20 | 1.58 | 24.91 | 25.07 | 0.09 |
| Example 18 | | | | | | | |
| Working | SiC | 0.69 | 3.10 | 2.14 | 24.93 | 25.05 | 0.07 |
| Example 19 | | | | | | | |
| Working | Cu | 0.38 | 8.92 | 3.39 | 24.97 | 25.02 | 0.03 |
| Example 20 | | | | | | | |
| Working | Cu | 0.38 | 8.92 | 3.39 | 25.00 | 25.01 | 0.01 |
| Example 21 | | | | | | | |

### Working Example 22

When the wafer holder manufactured in Working Example 21 was mounted in an exposure apparatus, and a resist was exposed, it was possible to form a good circuit pattern with no deviation of the exposure position.

1. A wafer holder configured and arranged to heat a semiconductor wafer placed on a wafer placement surface, said wafer holder comprising:
a heating plate including a heating section;
a cooling plate including a cooling section; and
a temperature measurement section configured and arranged to measure a temperature of the wafer holder,
said heating plate and said cooling plate being layered in a direction perpendicular to the wafer placement surface.

2. The wafer holder according to claim 1, wherein said heating plate is disposed closer to the wafer placement surface than said cooling plate.

3. The wafer holder according to claim 2, further comprising a heat conducting member disposed between said heating plate and said cooling plate.

4. The wafer holder according to claim 2, wherein
said cooling section is configured and arranged to perform cooling at a fixed output,
said heating section is configured and arranged to adjust output according to the temperature measured by said temperature measurement section.

5. The wafer holder according to claim 3, wherein
said cooling section of said cooling plate includes a Peltier element disposed between said cooling plate and said heat conducting member.

6. The wafer holder according to claim 3, wherein
said temperature measurement section is disposed inside said heat conducting member.

7. The wafer holder according to claim 6, wherein
a distance between said temperature measurement section and said heating plate is equal to or less than one-half of a thickness of said heat conducting member.

8. The wafer holder according to claim 7, wherein
said temperature measurement section contacts said heating plate.

9. The wafer holder according to claim 3, wherein
the planarity of said heat conducting member is equal to or less than 30 μm.

10. The wafer holder according to claim 9, wherein
the planarity of said heat conducting member is equal to or less than 10 μm.

11. The wafer holder according to claim 3, wherein
the surface roughness Ra of a contact surface between said heat conducting member and said cooling plate, and a contact surface between said heat conducting member and said heating plate is equal to or less than 3 μm.

12. The wafer holder according to claim 11, wherein
the surface roughness Ra of the contact surface between said heat conducting member and said cooling plate, and the contact surface between said heat conducting member and said heating plate is equal to or less than 1 μm.

13. The wafer holder according to claim 1, wherein
said heating plate includes a ceramic substrate, and
said heating section includes one of a metallized thin film, a metallic foil, and a metallic coil that is provided within or on a surface of the ceramic substrate.

14. The wafer holder according to claim 13, wherein
the thermal conductivity of the ceramic substrate is equal to or greater than 30 W/mK.

15. The wafer holder according to claim 14, wherein
the thermal conductivity of the ceramic substrate is equal to or greater than 50 W/mK.

16. The wafer holder according to claim 15, wherein
the thermal conductivity of the ceramic substrate is equal to or greater than 150 W/mK.

17. The wafer holder according to claim 13, wherein
the ceramic substrate is made of aluminum nitride.

18. The wafer holder according to claim 3, wherein
the heat conducting member is arranged such that the product of the specific heat and the density thereof is equal to or greater than 2.0 J/cm³K.

19. The wafer holder according to claim 18, wherein
the heat conducting member is arranged such that the product of the specific heat and the density thereof is equal to or greater than 2.3 J/cm³K.

20. The wafer holder according to claim 19, wherein
the heat conducting member is arranged such that the product of the specific heat and the density thereof is equal to or greater than 3.0 J/cm³K.

21. The wafer holder according to claim 3, wherein
said heat conducting member is made of one of copper and copper alloy.

22. The wafer holder according to claim 3, wherein
a target temperature of said wafer holder is set at a temperature between 10° C. and 40° C., and
said heating plate, said heat conducting member, and said cooling plate are pressed to form contacts between said heating plate and said heat conducting member and between said heat conducting member and said cooling plate.

23. An exposure apparatus including the wafer holder according to claim 1.
